(19) United States
(12) Patent Application Publication
(10) Pub. No.: US 2026/0090468 A1
(43) Pub. Date: Mar. 26, 2026

(54) ELECTRONIC ASSEMBLY AND METHOD OF FABRICATING THE SAME

(71) Applicant: TAIWAN SEMICONDUCTOR MANUFACTURING COMPANY LTD., HSINCHU (TW)

(72) Inventor: YU-HSUN LI, YUNLIN COUNTY (TW)

(21) Appl. No.: 18/895,437

(22) Filed: Sep. 25, 2024

(51) Int. Cl. H01L 25/00; H01L 23/00; H01L 23/473; H01L 23/498; H01L 25/065

(52) U.S. Cl. CPC H10W 90/00; H10W 40/47; H10W 70/635; H10W 90/701; H10W 90/724

(57) ABSTRACT

A method of fabricating an electronic assembly, includes steps of providing a stacked structure comprising an interposer and at least one heat generating device disposed over the substrate; forming a plurality of supporters on the interposer and laterally surround the heat generating device; forming a plurality of adhesive members on the supporters; and attaching a fluid-agitating device onto the adhesive members.

### BACKGROUND

Cooling is a prominent factor in data center design. A data center includes computing hardware and other electronic devices, such as CPU servers, GPU servers, storage servers, networking equipment, and the like. Proper operation of such electronic components is highly dependent on reliable removal of heat generated by the electronic components. Thus, proper cooling of the electronic components is crucial for overall system reliability.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 a schematic perspective view of a cooling system which receives a plurality of electronic assemblies, in accordance with some embodiments of the present disclosure.

FIG. 2 is a schematic perspective view of an electronic assembly and a carrier, in accordance with some embodiments of the present disclosure.

FIG. 3 is a schematic cross-sectional view of an electronic assembly, in accordance with some embodiments of the present disclosure.

FIG. 4 is a schematic perspective view of an electronic assembly and a carrier, in accordance with some embodiments of the present disclosure.

FIG. 5 is a schematic plan view of a fluid-agitating element device, in accordance with some embodiments of the present disclosure.

FIG. 6 is a schematic perspective view of an electronic assembly and a carrier, in accordance with some embodiments of the present disclosure.

FIG. 7 is a schematic cross-sectional view of an electronic assembly and a carrier, in accordance with some embodiments of the present disclosure.

FIG. 8 is a schematic perspective view of an electronic assembly and a carrier, in accordance with some embodiments of the present disclosure.

FIG. 9 is a schematic perspective view of an electronic assembly, in accordance with some embodiments of the present disclosure.

FIG. 10 is a schematic perspective view of an electronic assembly and a carrier, in accordance with some embodiments of the present disclosure.

FIG. 11 is schematic cross-sectional view of an electronic assembly and a carrier, in accordance with some embodiments of the present disclosure.

FIG. 12 is a schematic perspective view of an electronic assembly and a carrier, in accordance with some embodiments of the present disclosure.

FIG. 13 is a flowchart of a method of manufacturing an electronic assembly, in accordance with some embodiments of the present disclosure.

FIGS. 14 to 18 are cross-sectional views of intermediate stages of the method of manufacturing an electronic assembly, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence, order, or importance unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” or “about” generally mean within a value or range (e.g., within 10%, 5%, 1%, or 0.5% of a given value or range) that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another end point or between two endpoints. All ranges disclosed herein are inclusive of the endpoints, unless specified otherwise.

As computing demands continue to increase, heat dissipation requirements of electronic systems, such as computer systems and memory systems, are also rising. Resulting improvements in heat-dissipation capabilities are enabled by development of liquid-cooling technologies. Immersion cooling is a cooling technology used with electronic systems, by which the electronic systems are submerged in a thermally-conductive but electrically insulative fluid. Immersion cooling of electronic systems can increase power processing density and reliability in such electronic assemblies.

As required functionality of the electronic system increases, a number of chips required by the electronic system increases, and as density of the chips placed on a carrier substrate of the electronic system increases, it is increasingly difficult to conduct heat away or dissipate heat effectively from hot spots of the chips.

Accordingly, the present disclosure proposes to introduce a fluid-agitating device into the electronic system. The fluid-agitating device is disposed adjacent to the chips. The fluid-agitating device is capable of vibration, for example, during operation of the chips, thereby causing the fluid to be non-stationary. By disturbing the fluid, heat can be removed from the hot spots. Dissipation of heat from the electronic systems can be accomplished more quickly and more efficiently than is possible using existing immersion cooling technology.

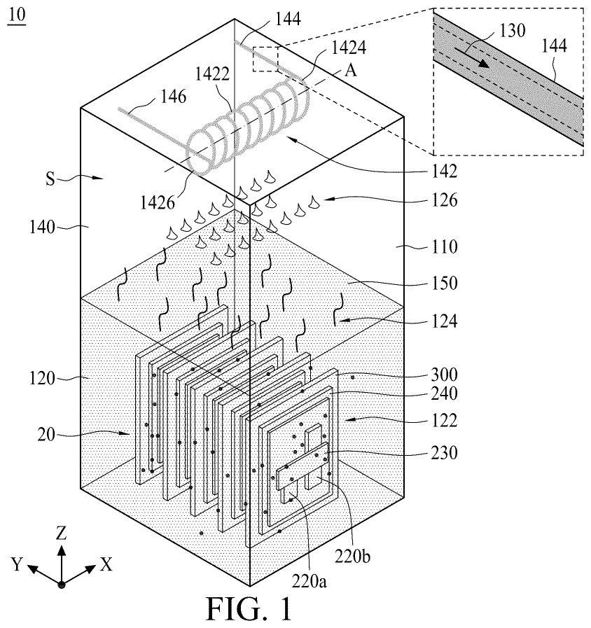

FIG. 1 is a schematic perspective view of a cooling system 10 that receives a plurality of electronic assemblies 20, in accordance with some embodiments of the present disclosure. Referring to FIG. 1, the cooling system 10 is adapted to cool the electronic assemblies 20 that generate a greater amount of heat during operation. The electronic assembles 20 may a part of server, capable of providing processing and storage capacity, in a data center. In some embodiments, the cooling system 10 is a fluid cooling system. The cooling system 10 may include a tank 110, fluids 120 and 130, and a condensing unit 140.

In some embodiments, the tank 110 defines a space S; the electronic assemblies 20, the fluids 120 and 130, and at least a portion of the condensing unit 140 are received inside the space S. The tank 110 may have a rectangular shape or a square shape from a top-view perspective. However, in some embodiments, the tank 110 includes a cylindrical shape or another suitable shape from the top-view perspective.

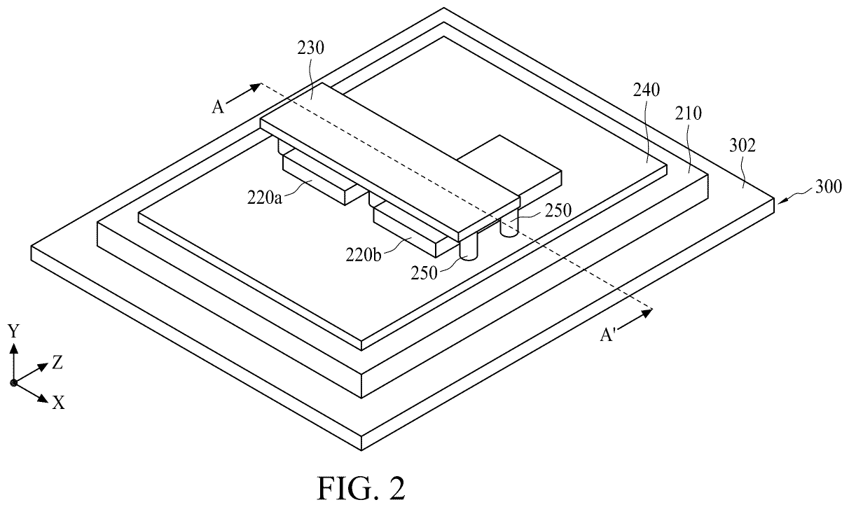

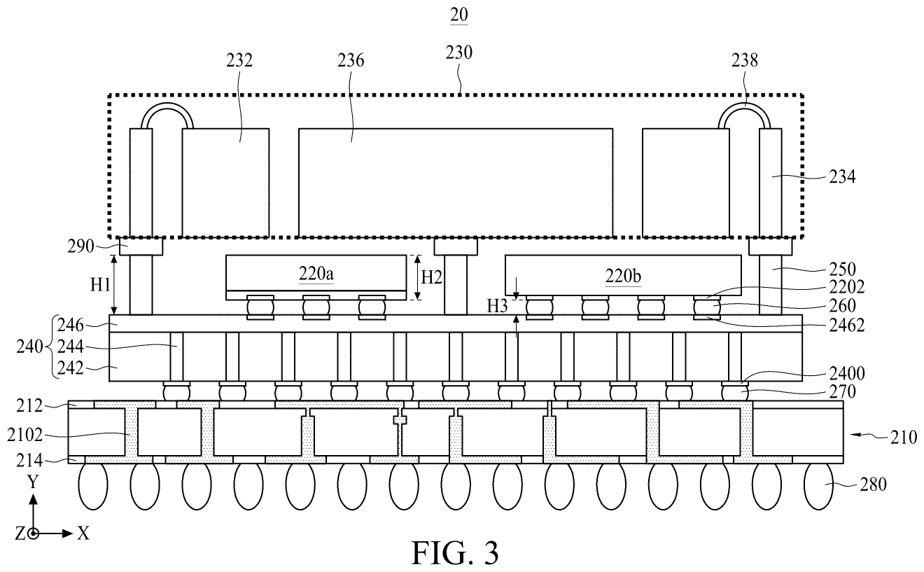

FIG. 2 is a schematic perspective view of the electronic assembly 20 and a carrier 300, in accordance with some embodiments of the present disclosure, and FIG. 3 is a schematic cross-sectional view of the electronic assembly 20, in accordance with some embodiments of the present disclosure. Referring to FIGS. 2 and 3, in some embodiments, the electronic assemblies 20 include a plurality of devices, such as one or more heat-generating devices (e.g., the heat-generating devices 220a and 220b) and a fluid-agitating device 230. The carrier 300 may be a printed circuit board and include a main surface 302, and the heat-generating devices 220a and 220b and the fluid-agitating device 230 are disposed over the main surface 302 of the carrier 300. The main surface 302 of the carrier 300 has a normal direction along the Y-direction. The heat-generating devices 220a/220b and the fluid-agitating device 230 may be vertically arranged along the normal direction. The heat-generating devices 220a and 220b may be chips including integrated active devices, such as transistors. In some embodiments, the heat-generating device 220a/220b is adapted to perform one or more predetermined function, such as logic, memory, processing, other functions, or combination thereof. The fluid-agitating device 230 is, for example, a micro-electro mechanical system (MEMS) capable of movement to agitate the fluid 120 within the tank 110.

Referring back to FIG. 1, in some embodiments, the carriers 300 are arranged in a line extending in the Y-direction, and the main surfaces 302 of all of the carrier 300 in the tank 110 face a same direction, so as to provide sufficient volume for fluid evaporation to effectively spread heat. The present disclosure, however, is not limited to the above configuration. In FIG. 1, four electronic assemblies 20 are presented in the tank 110. However, a number of the electronic assemblies 20 is not limited to that depicted in FIG. 1, and may be designed based on a dimension of the electronic assemblies 20 and a volume of the tank 110.

In some embodiments, the fluid 120 is a liquid fluid. The fluid 120, in a liquid state, does not fill the space S. For example, a volume of the fluid 120 is well controlled so that the space S is not completely filled; in some embodiments, for example, the space S is only half filled. The fluid 130 may be a gaseous fluid that fills a remainder of the space S not occupied by the fluid 120. The fluid 130 is above the fluid 120. The fluid 130 includes, but not limited to, air or a mixture of air and a vapor of the fluid 120. The space S may be an enclosed space in order to prevent or reduce the fluids 120 and 130 from dissipating outside the tank 110 during repeated cooling operations.

The fluid 120 is in thermal contact with the electronic assemblies 20 and serves to spread and dissipate heat from the electronic assemblies 20. In some embodiments, the fluid 120 is of sufficient volume to submerge the electronic assemblies 20. For example, the electronic assemblies 20 are entirely submerged within the fluid 120 when the electronic assemblies are operating. In other words, the electronic assemblies 20 are completely surrounded by the fluid 120. The electronic assemblies 20 may be below an interface 150 between the fluid 120 and the fluid 130. The interface 150 is also referred to herein as a fluid surface 150.

In some embodiments, the fluid 120 is a thermally conductive but electrically insulative fluid. The fluid 120 is in direct contact with the electronic assemblies 20 to conduct and spread heat away from the electronic assemblies 20, while the electronic assemblies 20 are not electrically connected to one another through the fluid 120. In some embodiments, the fluid 120 has a high resistance or a complete resistance to a flow of electrical current, and is thus able to provide an electrical isolation, thereby preventing electrical short between the electronic assemblies 20. For example, the fluid 120 is a liquid dielectric, such as deionized water, oil, coolant, or similar. In some embodiments, all devices of the electronic assemblies 20 are made of materials that are not soluble and do not break down within the tank 110 when in contact with the fluid 120. In some embodiments, a passivation coating (not shown) is applied to encapsulate the electronic assembly 20 to protect the electronic assembly 20 from damage or short circuit during operation in the fluid 120. The passivation coating may electrically isolate the electronic assembly 20 from the fluid 120 which is electrically conductive.

The space S may be configured to keep the fluid 120 free of dust, particles, and/or other contamination. As the electronic assemblies 20 are in direct contact with the fluid 120, minor contaminants can result in short circuits or damage to the electronic assemblies 20. Further, dust, particles, and/or other contamination may contaminate the fluid 120, and thus can degrade properties, including but not limited to the dielectric strength, of the fluid 120 as it becomes contaminated. If the dielectric strength of the fluid 120 is reduced, the electronic assemblies 20 immersed therein may short circuit or be otherwise damaged while in operation.

The heat generated or dissipated from the electronic assemblies 20 is directly absorbed by the fluid 120 in which the electronic assemblies 20 are submerged during operation. As the fluid 120 absorbs heat from the electronic assemblies 20, a temperature of the fluid 120 increases, and the fluid 120 cools the electronic assemblies 20. The fluid 120 has a boiling point at which is transitions from a liquid phase to a gas phase. In some embodiments, the boiling point of the fluid 120 is less than a temperature increase resulting from the heat generated by or dissipated from the electronic assemblies 20. Accordingly, the heat from the electronic assemblies 20 is sufficient to raise the temperature of portions of the fluid 120 surrounding the electronic assemblies 20 to the boiling point.

At the boiling point, at least a portion of the fluid 120 undergoes a phase change from the liquid phase to the gas phase by absorbing heat from the electronic assemblies 20, and bubbles of vapor (hereinafter, vapor bubbles) 122 are thus formed within the fluid 120. In other words, the vapor bubbles 122 may be created as the fluid 120 is vaporized due to the heat from the electronic assemblies 20. In some embodiments, the fluid 120 undergoing the liquid-to-vapor (or gas) transition absorbs more heat than the fluid 120 would absorb during a similar increase in temperature without the phase transition, and thus, the electronic assemblies 20 are further cooled. The vapor bubbles 122, carrying heat, have a lower density than the surrounding liquid fluid 120, and are therefore buoyant and rise upwards. Such buoyancy tends to raise the vapor bubbles 122 to the fluid surface 150, and the vapor bubbles 122 may break at the fluid surface 150, generating a vapor plume 124 flowing upward to the condensing unit 140. The electronic assemblies 20 are cooled by both the fluid 120 and the vapor bubbles 122.

The fluid-agitating device 230 may partially overlap the heat-generating devices 220a and 220b. In some embodiments, the fluid-agitating device 230 of the electronic assemblies is capable of moving or vibrating during operation of the electronic assemblies 20. In operation, the fluid-agitating device 230 may, for example, move or vibrate within the fluid 120 in response to the operation of the heat-generating devices 220a and 220b. The fluid-agitating device 230 is configured to generate sufficient movement or vibration to move the fluid 120 (e.g., by agitating) in the tank 110, to thereby assist in removing the vapor bubbles 122 from the fluid 120. The vapor bubbles 122, carrying heat, in the fluid 120, may rise faster to the fluid surface 150 by the movement or vibration of the fluid-agitating device 230, and therefore, the heat-generating devices 220 may be cooled more rapidly.

The condensing unit 140 is exposed to the fluid 120. The condensing unit 140 is not in contact with the fluid 120. In some embodiments, the condensing unit 140 serves to condense the vapor plume 124 into droplets 126, which eventually drop into the fluid 120. The condensing unit 140 is a gas-to-liquid phase condenser. The condensing unit 140 may include a heat exchanger 142, an inlet pipeline 144, an output pipeline 146, and the fluid 130 (as indicated in FIG. 1 by an arrow). The heat exchanger 142 includes a tubular duct 1422 for the flow of the fluid 130. The tubular duct 1422 may begin at an end 1424 and extend in a helical shape until it reaches an end 1426. In some embodiments, the tubular duct 1422 is coiled about an axis A of the helix, to thereby form a helically-shaped heat exchanger. The axis A may be parallel to the X-direction. In some embodiments, the heat exchanger 142 may include the tubular duct 1422 formed into a non-helical shape. The tubular duct 1422 may have a cross section in a shape of a circle, an ellipse, a square, a rectangle, or another suitable shape.

The heat exchanger 142 is above the fluid 120. The inlet pipeline 144 may extend from outside the tank 110 to inside the tank 110 and is connected to the end 1424 of the tubular duct 1422. The outlet pipeline 146 may extend from inside the tank 110 to outside the tank 110 and is connected to the end 1426 of the tubular duct 1422. In some embodiments, each of the inlet pipeline 144 and the outlet pipeline 146 includes two continuous segments, one of which is received in the tank 110 and connected to the heat exchanger 142, and the other of which is outside the tank 110 and, for example, exposed to ambient room air.

The inlet pipeline 144 and the outlet pipeline 146 may have a cross section same as the cross section of the tubular duct 1422. In some embodiments, the tubular duct 1422, the inlet pipeline 144, and the outline pipeline 146 are integrally formed. In alternative embodiments, the tubular duct 1422, the inlet pipeline 144, and the outlet pipeline 146 are discrete components that are secured to each other in a manner such that the components are not readily separable. For example, the inlet pipeline 144, the outlet pipeline 146 and the tubular duct 1422 may be fused together. The heat exchanger 142, the inlet pipeline 144, and the outlet pipeline 146 may be made of a metallic material with high thermal conductivity, such as, for example, steel, aluminum, or another suitable material.

In some embodiments, the fluid 130 enters the condensing unit 140 through the inlet pipeline 144 and travels to the outline pipeline 146 through the heat exchanger 142. The fluid 130 is, for example, water. The fluid 130 flows through the inlet pipeline 142 from an external fluid source, such as a reservoir (not shown). The fluid 130 that is to flow into the heat exchanger 142 has a first temperature. In some embodiments, the first temperature is less than a condensation temperature of the vapor plume 124.

The condensation of the vapor plume 124 causes the fluid 130, at the first temperature within the heat exchanger 142, to absorb heat from the vapor plume 124, thus causing the vapor plume 124 to convert (i.e., undergo a phase change) from the gas phase to the liquid phase. The resulting condensed cooling fluid (i.e., the droplets 126) may be condensed on the surface of the heat exchanger 142. In some embodiments, the droplets 126 fall from the heat exchanger 142, due to gravity, following condensation of the vapor plume 124. The droplets 126 are returned back to the fluid 120 in the bottom of the space S. The fluid 130 exiting the heat exchanger 142 through the outlet pipeline 146 may have a second temperature greater than the first temperature due to the absorption of the fluid 130 of a large amount of heat during the condensation of the vaporized fluid 122. The heated fluid 130 exits the condensing unit 140 and is cooled to a temperature at or below the first temperature, and then flows to the reservoir.

Referring back to FIGS. 2 and 3, in some embodiments, the electronic assembly 20 further includes a substrate 210, an interposer 240, a plurality of supporters 250, and a plurality of electrical connectors 260, 270 and 280. The interposer 240 is disposed between the heat-generating devices 220 and the substrate 210, and the substrate 210 is disposed between the interposer 240 and the carrier 300. The carrier 300, the substrate 210, the interposer 240, the heat-generating devices 220a and 220b, and the fluid-agitating device 230 may be vertically arranged along the Y-direction.

The interposer 240 may serve as an interconnection for connecting fine-pitch contact points of the heat-generating devices 220a and 220b to wider-pitch contact points of the substrate 210. In some embodiments, the electrical connectors 260 are located between the heat-generating devices 220a and 220b and the interposer 240, and electrically connect conductive pads 2202 of the heat-generating devices 220a and 220b to conductive pads 2462 of the interposer 240. The electrical connectors 270 are located between the interposer 240 and the substrate 210, and electrically connect conductive pads 2400 of the interposer 240 to traces 2102 of the substrate 210. The electrical connectors 270 are, for example, controlled collapse chip connection (“C4”) bumps. The electrical connectors 280 are placed on a rear surface of the substrate 210. The electrical connectors 280 may be solder balls arranged as a ball grid array (“BGA”). The electrical connectors 280 may be mounted on the rear surface 214 of the substrate 210.

In some embodiments, the interposer 240 includes a substrate 242, a plurality of through-substrate vias 244, and an interconnect structure 246. The substrate 242 may be formed of a semiconductor material such as silicon. The through-substrate vias 244 penetrate through the substrate 242. The conductive pads 2400 may be physically and electrically connected to the through-substrate vias 244. In some embodiments, each of the through-substrate vias 244 may be laterally surrounded by an insulative film (not shown) to isolate the through-substrate vias 244 from other connections. The insulative film may provide protection against copper diffusion when the through-substrate vias 244 include copper. The insulative film includes dielectric material, such as oxides or nitrides, and/or other suitable dielectric materials.

The interconnect structure 246 is disposed between the through-substrate vias 244 and the electrical connectors 260 and between the substrate 242 and the supporters 250. In some embodiments, the interconnect structure 246 is electrically connected to the through-substrate vias 244. In some embodiments, the interconnect structure 246 includes a trace, including the conductive pads 2462, disposed in one or more dielectric layers 2464. The dielectric layer(s) 2464 may include, for example, oxide, nitride, carbide, oxynitride, or the like, and the trace (i.e., the conductive pads 2462) may include copper, tungsten, aluminum, silver, gold, or another suitable electrically conductive material.

The interposer 240 may be substantially free from integrated circuit devices, including active components such as transistors and diodes. In some embodiments, the interposer 240 is free from passive components, such as capacitors, resistors, inductors, and/or the like. In alternative embodiments, the interposer 240 includes passive components disposed in or on the substrate 242 and/or the interconnect structure 246. The passive components and the trace of the interconnect structure 246 may be interconnected to perform one or more functions, such as power distribution, input/output circuitry, or the like.

In some embodiments, the heat-generating devices 220a and 220b are mounted on the interposer 240 using the conductive connectors 260. The conductive connectors 260 may be solder bumps. In some embodiments, the conductive connectors 260 are placed on and electrically connected to the interconnect structure 246 of the interposer 240. A thermal reflow process may then be used to cause the electrical connectors 260 to soften and form electrical and mechanical connections between the heat-generating devices 220 and the interposer 240.

The interposer 240 may be mounted to the substrate 210 using the conductive connectors 270. The conductive connectors 270 are, for example, controlled collapse chip connection (“C4”) bumps, and attached to the main surface 212 of the substrate 210. The substrate 210 may further include a rear surface 214 opposite to the main surface 212. The rear surface 214 of the substrate 210 has the electrical connectors 280, such as ball grid array (“BGA”) balls.

The supporters 250 are disposed on the interconnect structure 246 of the interposer 240. The supporters 250 are disposed at opposite sides of the heat-generating device 220a and 220b. As shown in FIG. 3, the supporters 250 and the heat-generating devices 220a and 220b are staggered along the X direction to provide sufficient support for the fluid-agitating device 230. The supporters 250 have a height H1, which may be greater than a combined height of the heat-generating device 220a/220b and the electrical connectors 260. For example, the heat-generating device 220a/220b has a height H2, and the electrical connectors 260 have a height H3. The supporters 250 have the height H1 greater than a sum of the height H2 and the height H3, and therefore, the fluid-agitating device 230 is not in contact with the heat-generating devices 220a/220b. The supporters 250 may have a cross section in a shape of a circle, an ellipse, a square, a rectangle, or another suitable shape. The supporter 250 is made of material with a high heat transfer coefficient (k), so as to be able to assist in transferring heat from the electronic assembly 20 to the fluid 120. The supporter 250 is made of metal. In some embodiments, the supporter 250 is made of aluminum copper alloy, iron, silver, gold, or another suitable material. The supporter 250 may have the heat transfer coefficient of greater than 20 W/mK.

The fluid-agitating device 230 is attached to the supporters 250 by adhesive members 290. The adhesive members 290 may be epoxy, die attach film (DAF), or any suitable adhesive which is not soluble and which does not otherwise break down within the tank 110 when in contact with the fluid 120.

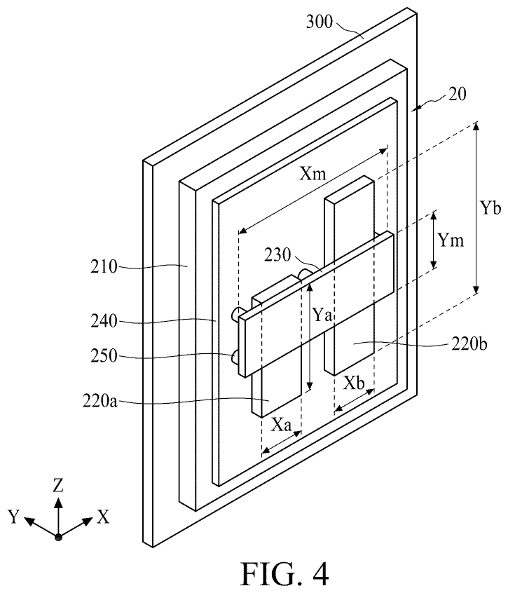

FIG. 4 is a schematic perspective view of the electronic assembly 20, in accordance with some embodiments of present disclosure. Referring to FIG. 4, the fluid-agitating device 230 may partially overlap the heat-generating device 220a/220b from a top-view perspective. For example, the heat-generating device 220a has a width Xa in the X-direction and a length Ya in the Y-direction, and the heat-generating device 220b has a width Xb in the X-direction and a length Yb in the Y-direction. The fluid-agitating device 230 has a length Xm in the X-direction and a width Ym in the Y-direction. The length Xm of the fluid-agitating device 230 may be greater than a sum of the width Xa and the width Xb of the heat-generating devices 220a and 220b. The length Ya/Yb of the heat-generating device 220a/220b may be greater than the width Ym of the fluid-agitating device 230. In some embodiments, opposite edges of the heat-generating device 220b parallel to the X-direction are exposed through the fluid-agitating device 230; an edge of the heat-generating device 220a parallel to the X-direction is exposed through the fluid-agitating device 230, and another edge of the heat-generating device 220a parallel to the X-direction is covered by the fluid-agitating device 230.

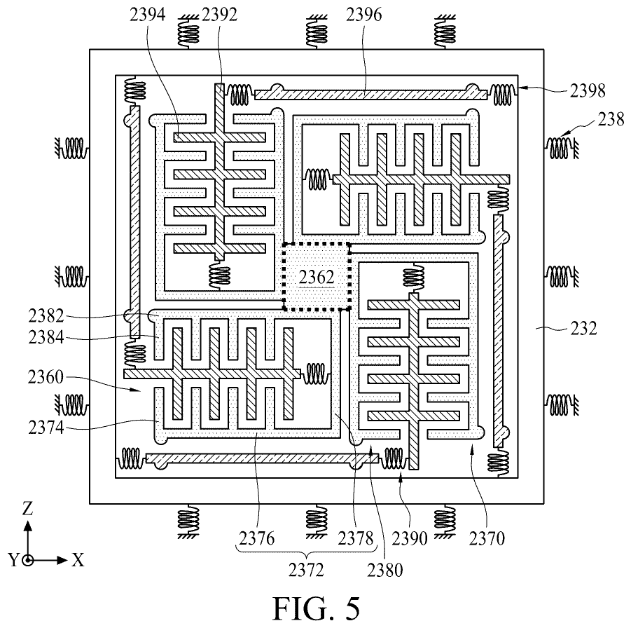

FIG. 5 is a schematic plan view of the fluid-agitating device 230, in accordance with some embodiments of present disclosure. Referring to FIGS. 3 and 5, in some embodiments, the fluid-agitating device 230 includes an inner frame 232, an outer frame 234, an accelerometer 236, and a plurality of wires 238. The inner frame 232 may have a rectangular or a squared-ring shape from a top view perspective. In some embodiments, the inner frame 232 is laterally surrounded by the outer frame 234 and electrically connected to the outer frame 234 by the wires 238. The outer frame 234 may be attached to the adhesive members 290.

The accelerometer 236 may be laterally surrounded by the inner frame 234 and may include a fixed electrode assembly 2360 and a plurality of movable electrodes 2390. As shown in FIG. 5, the fixed electrode assembly 2360 does not physically contact the inner frame 232. The fixed electrode assembly 2360 may include a base 2362, a plurality of first fixed electrodes 2370, and a plurality of second fixed electrodes 2380, wherein the first and second fixed electrodes 2370 and 2380 are connected to the base 2362. In some embodiments, the base 2362 has a rectangular or square shape from a top view perspective, and the first and second fixed electrodes 2370 and 2380 and the movable electrodes 2390 are disposed around the base 2362. A number of the first fixed electrodes 2370 may be same as a number of the second fixed electrodes 2380. A number of the movable electrodes 2390 may be same as the number of the first fixed electrodes 2370. For example, the accelerometer 236 has four first fixed electrodes 2370, four second fixed electrodes 2380, and four movable electrodes 2390. However, the number of the first fixed electrodes 2370 is not limited in the disclosure.

Each of the first fixed electrodes 2370 may include a connecting member 2372 and a first set of fingers 2374 connected to the connecting member 2372. In some embodiments, the connecting member 2372 includes an edge segment 2376 and an interconnect segment 2378 extending from the base 2362 to the edge segment 2376. The edge segment 2376 may be perpendicular to the interconnect segment 2378, so that the connecting member 2372 may be L-shaped from a top-view perspective. The fingers 2374 may extend from one side of the edge segment 2376 of the first fixed electrodes 2370. In some embodiments, the fingers 2374 in each first fixed electrode 2370 are perpendicular to the edge segment 2376 of the first fixed electrodes 2370 in the same first fixed electrode 2370. The first fixed electrodes 2370 may have a comb shape that includes, for example, four fingers 2374. However, a number of the fingers 2374 in each of the first fixed electrodes 2370 is not limited in the disclosure.

In some embodiments, the second fixed electrode 2380 includes a connecting member 2382 connected to the base 2362 and a second set of fingers 2384 extending from one side of the connecting member 2382. The connecting member 2382 may be I-shaped form a top-view perspective. In some embodiments, the connecting member 2382 is parallel to the edge segment 2376 of the connecting member 2372. The fingers 2384 may extend from one side of the connecting member 2382. The fingers 2384 in each second fixed electrode 2380 may be, for example, perpendicular to the connecting member 2382 in the same second fixed electrode 2380. The second fixed electrodes 2380 may have another comb shape that includes, for example, four fingers 2384. However, a number of the fingers 2384 in each second fixed electrode 2380 is not limited in the disclosure.

In some embodiments, each of the movable electrodes 2390 includes a connecting member 2392 and a plurality of ribs 2394 crossing the connecting member 2392. The connecting members 2392 do not physically contact the inner frame 232. A number of the ribs 2394 may be same as the numbers of the fingers 2374/2384. For example, the movable electrodes 2390 include four ribs 2394. In some embodiments, the ribs 2394 in each movable electrode 2390 are perpendicular to the connecting members 2392 in the same movable electrode 2390.

In some embodiments, one of the first fixed electrodes 2370, one of the second fixed electrodes 2380, and one of the movable electrodes 2390 are disposed side by side, wherein the movable electrode 2390 is between the first and second fixed electrodes 2370 and 2380. In addition, the fingers 2374 of the first fixed electrode 2370 may face and align with the fingers 2384 of the second fixed electrode 2380; the fingers 2374 and 2384 are interleaved with the ribs 2394, so that the ribs 2394 are each positioned between two fingers 2374/2384.

In some embodiments, the accelerometer 236 further includes a plurality of cantilevers 2396 and a plurality of hinges 2398. Each of the cantilevers 2396 may be surrounded by one of the first fixed electrodes 2370, one of the second fixed electrodes 2380, one of the movable electrodes 2390, and the inner frame 232. In some embodiments, the cantilevers 2396 are I-shaped form a top-view perspective; one terminal of the cantilevers 2396 is connected to the movable electrode 2390 through a hinge 2398 and another terminal of the cantilevers 2396 is connected to the inner frame 232 by another hinge 2398.

In some embodiments, the fixed electrode assembly 2360 and the movable electrodes 2390 are electrically connected to a power supply (not shown). When voltages are applied to the fixed electrode assembly 2360 and the movable electrodes 2390, electrostatic forces may be generated between the fixed electrode assembly 2360 and the movable electrode 2390. As a result, the cantilever 2396 parallel to the X-direction may be expanded and contracted along the X-direction, and the cantilever 2396 parallel to the Z-direction may be expanded and contracted along the Z-direction, and the accelerometer 236 may be moved or vibrated along the X-Z plane.

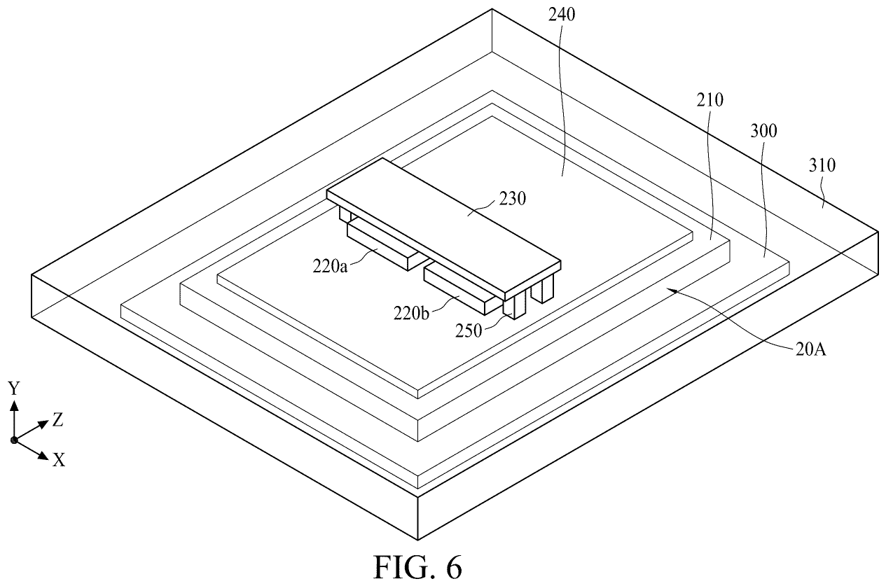

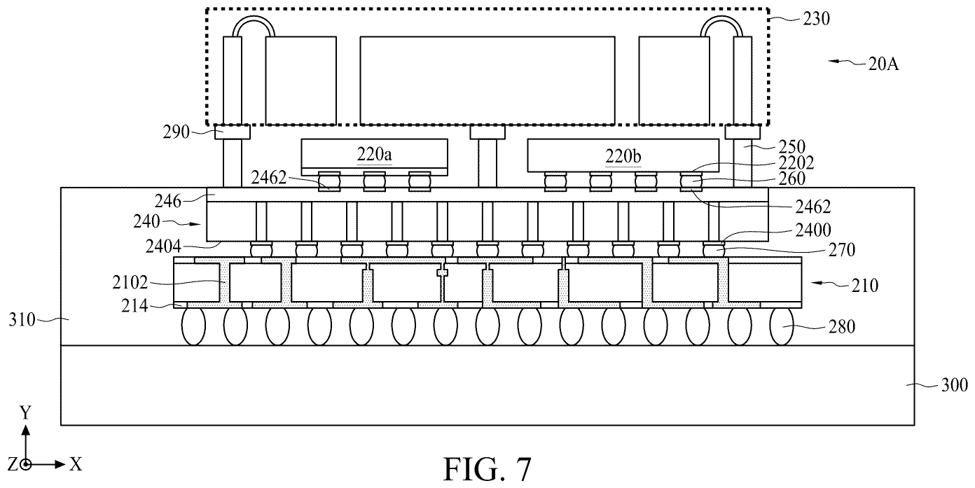

FIG. 6 is a schematic perspective view of an electronic assembly 20A and a carrier 300, in accordance with some embodiments of present disclosure, and FIG. 7 is a schematic cross-sectional view of the electronic assembly 20A, in accordance with some embodiments of present disclosure. The electronic assembly 20A is similar to the electronic assembly 20 discussed above, except that the electronic assembly 20A further includes an encapsulant 310. Referring to FIGS. 6 and 7, the encapsulant 310 covers the carrier 300, the substrate 210, and the interposer 240, while exposing the heat-generating devices 220a and 220b and the fluid-agitating device 230. In some embodiments, the encapsulant 310 laterally surrounds the substrate 210, the interposer 240, the electrical connectors 270 and 280, and conductive pads 2400 disposed on a rear surface 2404 of the interposer 240.

The electrical connectors 260 may be exposed through the encapsulant 310. In some embodiments, the encapsulant 310 has an upper surface 3102 coplanar with an upper surface 2402 of the interposer 240, wherein the interconnect structure 246 of the interposer 240 is in contact with the upper surface 2402 of the interposer 240. The encapsulant 310 may be formed around the heat-generating devices 220a and 220b and the fluid-agitating device 230. The encapsulant 310 may include a polymer, which may be a molding compound, an underfill, or the like.

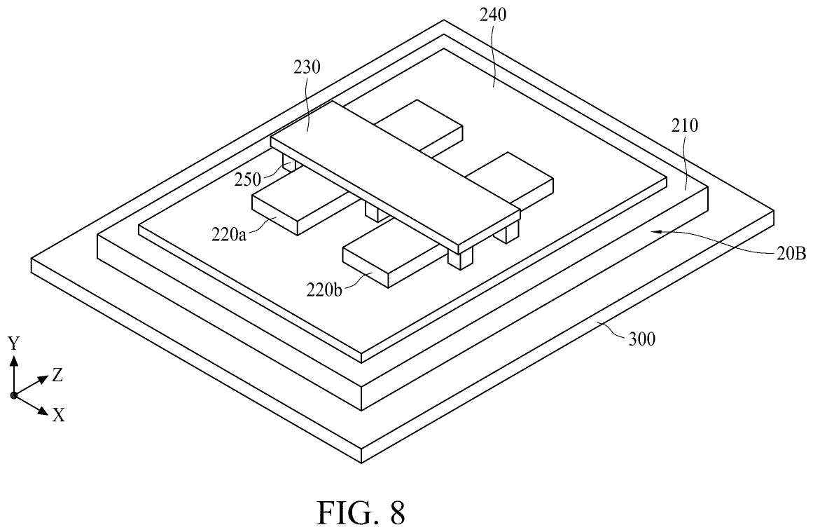

FIG. 8 is a schematic perspective view of an electronic assembly 20B and a carrier 300, in accordance with some embodiments of present disclosure. The electronic assembly 20B is similar to the electronic assembly 20 discussed above, except for arrangement of the heat-generating devices 220a and 220b and the fluid-agitating device 230. Referring to FIG. 8, in some embodiments, the heat-generating device 220a/220b and the fluid-agitating device 230 partially overlap. The heat-generating devices 220a and 220b extend in the Z-direction, and the fluid-agitating device 230 extends in the X-direction orthogonal to the Z-direction. The fluid-agitating device 230 may cross over the heat-generating devices 220a and 220b. In some embodiments, the fluid-agitating device 230 crosses two opposite edges, parallel to the Z-direction, of the heat-generating devices 220a and 220b. Two opposite edges of the heat-generating devices 220a and 220b, parallel to the X-direction, are exposed through the fluid-agitating device 230.

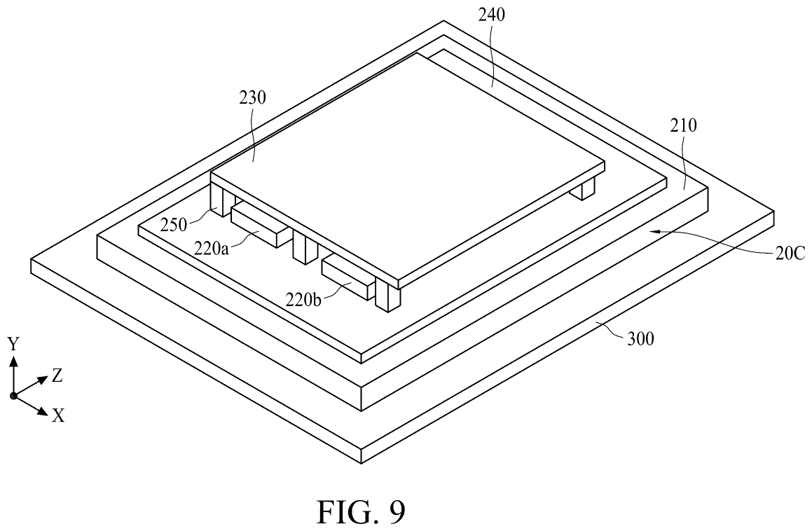

FIG. 9 is a schematic perspective view of an electronic assembly 20C and a carrier 300, in accordance with some embodiments of present disclosure. The electronic assembly 20C is similar to the electronic assembly 20 discussed above, except for arrangement of the heat-generating devices 220a and 220b and the fluid-agitating device 230. Referring to FIG. 9, in some embodiments, the fluid-agitating device 230 fully overlaps and covers the heat-generating devices 220a and 220b. A footprint of the fluid-agitating device 230 may be larger than footprints of the underlying heat-generating devices 220a and 220b. In some embodiments, outer edges of the heat-generating devices 220a and 220b are covered by the fluid-agitating device 230.

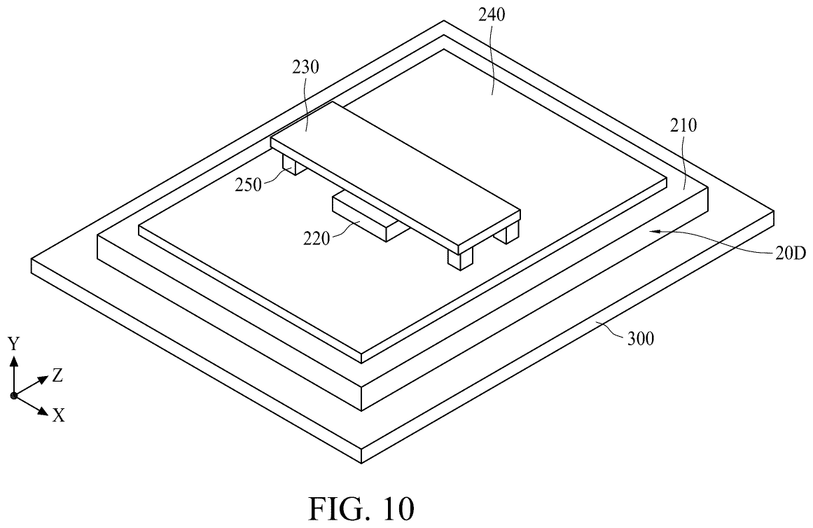

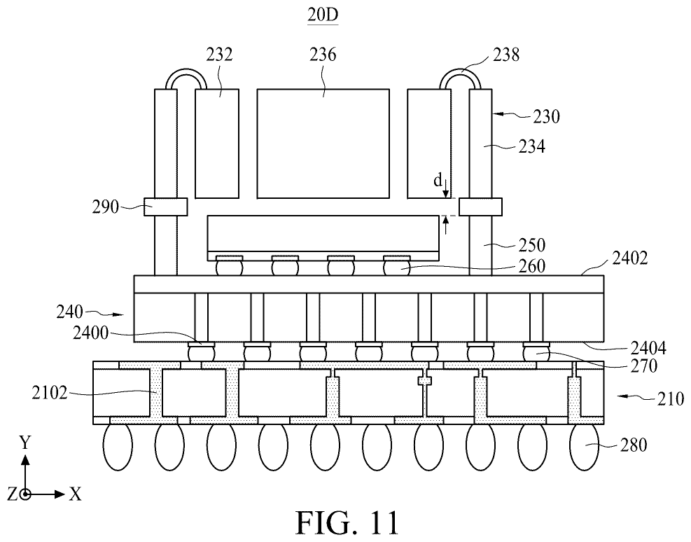

FIG. 10 is a schematic perspective view of an electronic assembly 20D and a carrier 300, in accordance with some embodiments of present disclosure, and FIG. 11 is a schematic cross-sectional view of the electronic assembly 20D, in accordance with some embodiments of present disclosure. Referring to FIGS. 10 and 11, in some embodiments, the electronic assembly 20D is disposed on the carrier 300 and includes a substrate 210, a heat-generating device 220, a fluid-agitating device 230, an interposer 240, a plurality of supporters 250, and a plurality of electrical connectors 260, 270 and 280.

The substrate 210, the interposer 240, the heat-generating device 220, and the fluid-agitating device 230 are vertically arranged along the Y-direction. The electrical connectors 260 and the supporters 250 are disposed on an upper surface 2402 of the interposer 240. The electrical connectors 260 connect the heat-generating device 220 to the interposer 240. The supporters 250 may laterally surround the heat-generating device 220 and include metallic material for transferring heat to the fluid 120 (as shown in FIG. 1) during operation of the heat-generating device 220.

The electrical connectors 270 are electrically connected to a plurality of conductive pads 2400 on a rear surface 2404 of the interposer 240. The electrical connectors 270 are further electrically connected to the electrical connector 280 by traces 2102 in the substrate 210. In some embodiments, the heat-generating device 220 and the fluid-agitating device 230 at least partially overlap. The heat-generating device 220 extends along the Z-direction, the fluid-agitating device 230 extends along the X-direction orthogonal to the Z-direction, and the fluid-agitating device 230 may cross over the heat-generating device 220. At least an edge of the heat-generating device 220, parallel to the X-direction, is exposed to the fluid-agitating device 230.

The fluid-agitating device 230 may include an inner frame 232, an outer frame 234, an accelerometer 236, and a plurality of wires 238. The inner frame 232 is connected to the outer frame 234 by the wires 238. The outer frame 234 is attached to the supporters 250 by adhesive members 290. In some embodiments, the accelerometer 236 is laterally surrounded by the inner frame 234 and disposed above the heat generating device 220. The accelerometer 236 may be spaced apart from the heat generating device 220 by a distance D. The accelerometer 236 is not in physical contact with the heat generating device 220. In some embodiments, the accelerometer 236 is capable of vibrating during operation of the heat generating device 220.

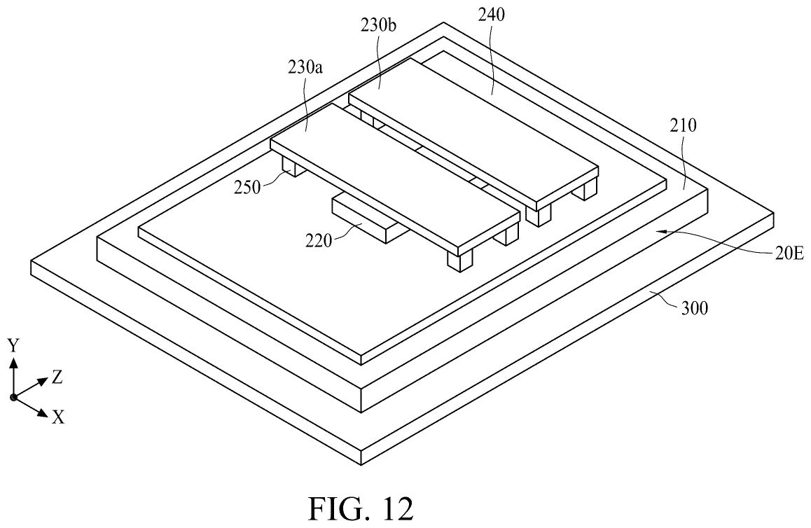

FIG. 12 is a schematic perspective view of an electronic assembly 20E and a carrier 300, in accordance with some embodiments of present disclosure. The electronic assembly 20E is similar to the electronic assembly 20D discussed above, except that the electronic assembly 20E includes a plurality of fluid-agitating devices 230a and 230b. Referring to FIG. 12, in some embodiments, the fluid-agitating devices 230a/230b partially overlap the heat-generating device 220. The heat-generating device 220 may extend in the Z-direction, and the fluid-agitating devices 230a and 230b extend in the X-direction. The fluid-agitating devices 230a and 230b are placed side by side atop the heat-generating device 220.

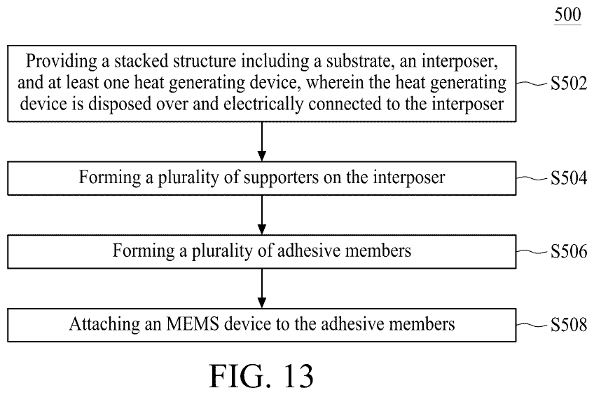

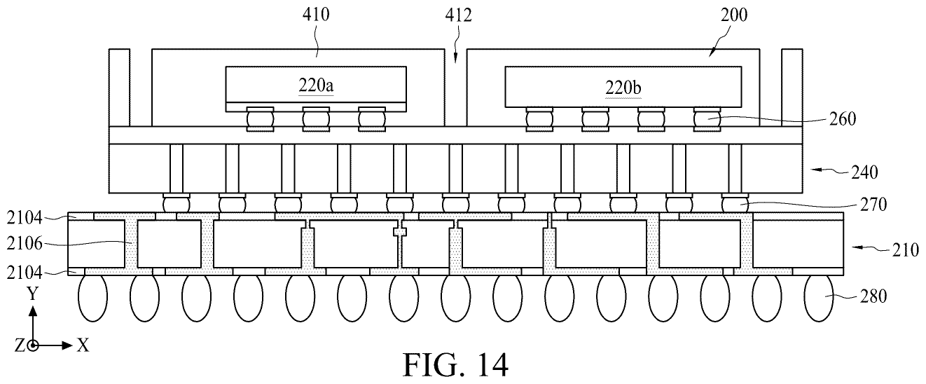

FIG. 13 is a flowchart of a method 500 of manufacturing an electronic assembly 20, in accordance with some embodiments of the present disclosure. FIGS. 14 to 18 are cross-sectional views of intermediate stages of the method 500 of manufacturing the electronic assembly 20, in accordance with some embodiments of the present disclosure. In the following description, the manufacturing stages shown in FIGS. 14 to 18 are discussed with reference to the process steps shown in FIG. 13. It should be understood that additional steps can be provided before, during, and after the steps shown in FIG. 13, and some of the steps described below can be replaced or eliminated, for additional embodiments of the method 500. An order of the steps may be changed.

Referring to FIG. 14, in accordance with step S502 in FIG. 13, in some embodiments, a stacked structure 200 including a substrate 210, a plurality of heat-generating devices 220a and 220b, and an interposer 240 is provided. The substrate 210 may be a part of a wafer or a bulk substrate formed of bulk material. In some embodiments, the substrate 210 includes a silicon substrate, or the like. The substrate 210 may include multiple conductive lines 2104, some of which are inter-layers within the substrate 200. These layers may be etched into traces of various widths and lengths and connected through conductive vias 2106. Together, the conductive lines 2104 and the conductive vias 2106 may form an electrical network to route power, ground, and signals from a top surface of the substrate 200 to a bottom surface of the substrate 200.

The interposer 240 is disposed over the substrate 200 and are electrically connected to the conductive lines 2104 by a plurality of electrical connectors 270. The heat-generating devices 220a and 220b are disposed over the interposer 240 and are electrically connected to the interposer 240 by a plurality of electrical connectors 260.

Subsequently, a first patterned mask layer 410 is formed over the interposer 240 and the heat-generating devices 220a and 220b, wherein the first patterned mask layer 410 includes a plurality of first openings 412. Portions of the interposer 240 are exposed through the first openings 412. Although three first openings 412 are illustrated in FIG. 14, such number of the first openings 412 in the first patterned mask layer 410 is not intended to be limiting. For example, the first patterned mask layer 410 may include more than three first openings 412 to laterally surround the heat-generating devices 220a and 220b. A shape of the first openings 412 may be adjusted as required. In some embodiments, the first patterned mask layer 410 may include a photoresist, and the first openings 412 are formed by a lithography operation.

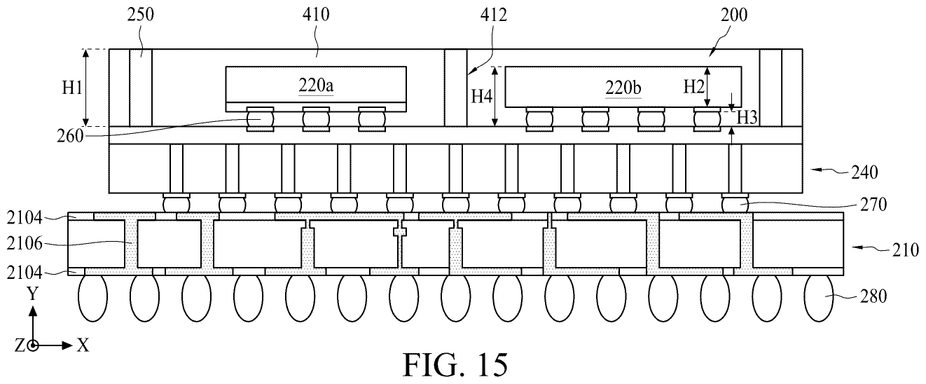

Referring to FIG. 15, in accordance with step S504 in FIG. 13, a conductive material is provided to fill the first openings 412. Hence, a plurality of supporters 250 are formed. In some embodiments, the conductive material is deposited and forms the supporters 250 on the interposer 240 and laterally surrounding the heat-generating devices 220a and 220b. Examples of the conductive material include, but are not limited to, iron, silver, gold, an aluminum-copper alloy, and the like. The conductive material may be formed or deposited by an electro-chemical plating process, a CVD process, a PVD process, an ALD process, or another applicable deposition operation. After the conductive material fills or is deposited in the first openings 412, excess portions of the conductive material are removed to expose a top surface 414 of the first patterned mask layer 410. The excess portions of the conductive material may be removed by a CMP operation. After the formation of the supporters 250, a removal operation such as stripping or ozone ashing is performed to remove the first patterned mask layer 410.

The supporters 250 have a height H1, which may be greater than a combined height H4 of the heat-generating device 220a/220b and the electrical connectors 260 above the interposer 240. In some embodiments, the heat-generating device 220a/220b has a height H2, and the electrical connectors 260 have a height H3, and the combined height H4 is equal to a sum of the height H2 and the height H3.

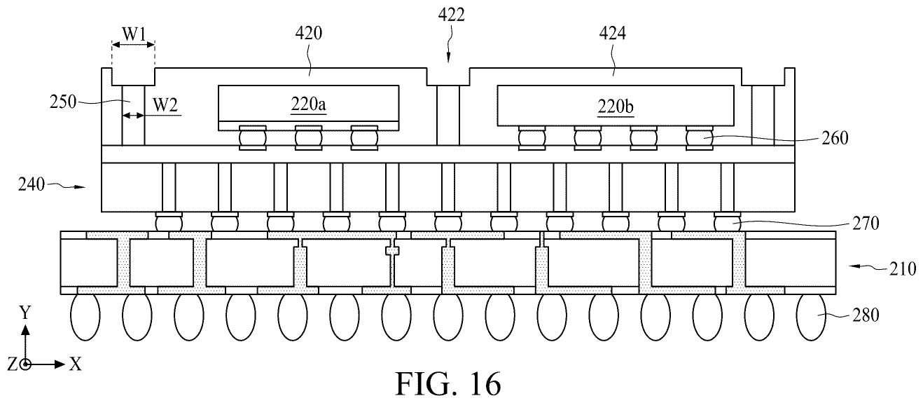

Referring to FIG. 16, a second patterned mask layer 420 is formed on the portions of the interposer 240. The second patterned mask layer 420 includes a plurality of second openings 422 to expose the supporters 250. From a cross-sectional perspective, the second openings 422 may have a width W1 greater than a width W2 of the supporters 250.

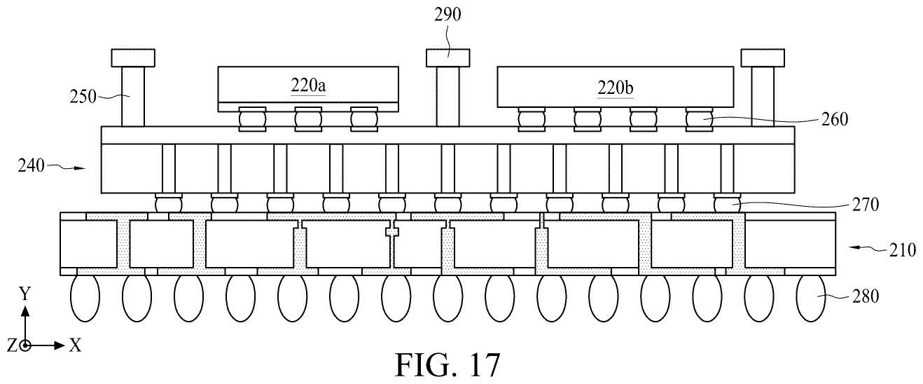

In accordance with step S506 of FIG. 13, after the formation of the second openings 422, an adhesive material is provided to fill the second openings 422. Referring to FIGS. 16 and 17, in some embodiments, the adhesive material is deposited and forms adhesive members 290 in physical contact with the supporter 250. After the adhesive material fills or is deposited in the second openings 422, an excess portion of the adhesive material is removed to expose a top surface 424 of the second patterned mask layer 420. The adhesive members 290 may include a thermal glue or another thermal interface material, enabling the distribution or disposal of the heat generated by the heat-generating devices 220a and 220b and the fluid-agitating device 230 and allowing the heat to be dissipated outwardly to the fluid 120 (shown in FIG. 1). After the formation of the adhesive members 290, a removal operation such as stripping or ozone ashing is performed to remove the second patterned mask layer 420.

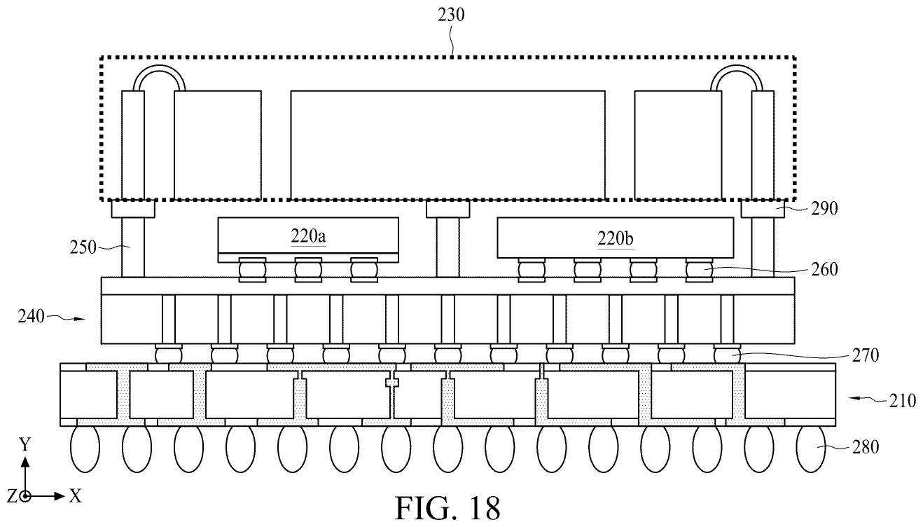

Referring to FIG. 18, in accordance with step S508 of FIG. 13, a fluid-agitating device 230 is attached to the adhesive members 290. Consequently, the electronic assembly 20 is completely formed. Attaching the fluid-agitating device 230 may include placing the fluid-agitating device 230 on the adhesive members 290 using a pick-and-place tool or the like. However, any other method of placing the fluid-agitating device 230 onto the adhesive members 290 may also be utilized.

In accordance with some embodiments of the present disclosure, a method of fabricating an electronic assembly includes steps of providing a stacked structure comprising an interposer and at least one heat-generating device disposed over and electrically connected to the substrate; forming a plurality of supporters on the interposer and laterally surrounding the heat-generating device; forming a plurality of adhesive members on the supporters; and attaching a fluid-agitating device onto the adhesive members.

In accordance with some embodiments of the present disclosure, a method of fabricating an electronic assembly includes steps of providing an interposer; mounting a heat generating device to the interposer, wherein the heat generating device is electrically coupled to the interposer; and mounting a fluid-agitating device on the interposer, wherein the fluid-agitating device comprises an accelerometer above the heat generating device.

In accordance with some embodiments of the present disclosure, an electronic assembly includes an interposer; a heat-generating device disposed over and electrically connected to the interposer; and a fluid-agitating device disposed over the heat-generating device, wherein the fluid-agitating device and the heat-generating device at least partially overlap.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating an electronic assembly, comprising:
providing a stacked structure comprising an interposer and at least one heat generating device disposed over and electrically connected to the interposer;
forming a plurality of supporters on the interposer and laterally surround the heat generating device; and
attaching a fluid-agitating device onto the plurality of supporter,
wherein the fluid-agitating device and the heat generating device at least partially overlap.

2. The method of claim 1, wherein the fluid-agitating device fully overlap with the heat generating device.

3. The method of claim 1, further comprising forming a plurality of adhesive members on the supporters prior to the attachment of the fluid-agitating device to the plurality of supporters, wherein the fluid-agitating device is attached to the plurality of supporters by the plurality of adhesive members.

4. The method of claim 3, wherein the plurality of supporters have a first width greater than a second width of the plurality of adhesive members.

5. The method of claim 1, wherein:
the stacked structure further comprises a plurality of first electrical connectors, and the heat generating device is connected to the interposer by the plurality of first electrical connectors, and
the plurality of supporters have a first height, the heat generating device has a second height, the plurality of first electrical connectors have a third height, and the first height is greater than a sum of the second height and the third height.

6. The method of claim 1, wherein the supporters are disposed at opposite sides of the heat generating device.

7. The method of claim 1, wherein the fluid-agitating device comprises:
an outer frame attached to the plurality of supporter;
an accelerometer laterally surrounded by the outer frame, wherein the accelerometer comprises:
a plurality of first fixed electrodes each comprising a plurality of first fingers;
a plurality of second fixed electrodes each comprising a plurality of second fingers;
a plurality of movable electrode each comprising a plurality of ribs,
wherein each movable electrode is between one of the first fixed electrodes and one of the second fixed electrodes, and the first and second fingers are interleaved with the ribs.

8. The method of claim 7, wherein the fluid-agitating device further comprises:
a plurality of cantilevers surrounded by the inner frame, one of the first fixed electrodes, and one of the second fixed electrode; and
a plurality of hinges connecting the plurality of cantilevers to the inner frame and the movable electrodes.

9. The method of claim 7, wherein:
each of the first fixed electrodes further comprises a first connecting member, and the first fingers extend from one side of the first connecting member;
each of the second fixed electrodes further comprises a second connecting member, and the second fingers extend from one side of the second connecting member; and
each of the movable electrodes further comprises a third connecting member, and the ribs cross the third connecting members.

10. The method of claim 1, wherein the supporters comprises metallic material.

11. The method of claim 1, wherein the interposer comprises:
a first substrate;
a plurality of through-silicon vias penetrate through the first substrate; and
an interconnect structure disposed on the first substrate, wherein the heat generating device and the plurality of supporters are in contact with the interconnect structure.

12. The method of claim 1, wherein the stacked structure further comprises:
a carrier;
a second substrate disposed over the carrier;
a plurality of second electrical connectors, wherein the interposer is connected to the substrate by the plurality of second electrical connectors; and
a plurality of third electrical connectors, wherein the substrate is connected to the carrier by the plurality of third electrical connectors.

13. A method of fabricating an electronic assembly, comprising:
providing an interposer;
attaching a heat generating device to the interposer; and
mounting a fluid-agitating device on the interposer, wherein the fluid-agitating device comprises an accelerometer above the heat generating device.

14. The method of claim 13, wherein the accelerometer is spaced apart from the accelerometer by a distance.

15. The method of claim 13, further comprising:
forming a plurality of supporters on the interposer and laterally surround the heat generating device, wherein the fluid-agitating device is mounted on the interposer by the supporters.

16. The method of claim 15, further comprising forming a plurality of adhesive members on the plurality of supporters, wherein the fluid-agitating device is mounted to the interposer by the plurality of supporters and the plurality of adhesive members.

17. The method of claim 13, wherein the supporters comprises metallic material.

18. An electronic assembly, comprising:
an interposer;
a heat generating device disposed over the interposer;
a plurality of supporters disposed on the interposer; and
a fluid-agitating device attached to the supporters,
wherein the fluid-agitating device and the heat generating device at least partially overlap.

19. The electronic assembly of claim 18, further comprises a plurality of adhesive members, wherein the fluid-agitating device is attached to the plurality of the supporters by the plurality of adhesive members.

20. The electronic assembly of claim 18, wherein the fluid-agitating device fully overlap with the heat generating device.
